(19) United States
(12) Patent Application Publication
(10) Pub. No.: US 2014/0264393 A1
(43) Pub. Date: Sep. 18, 2014

(54) LIGHT ENGINE

(71) Applicant: ABL IP HOLDING LLC, Conyers, GA (US)

(72) Inventor: Forrest Starnes McCanless, Oxford, GA (US)

(73) Assignee: ABL IP HOLDING LLC, Conyers, GA (US)

(21) Appl. No.: 13/802,982

(22) Filed: Mar. 14, 2013

(51) Int. Cl. H01L 33/64

(52) U.S. Cl. CPC H01L 33/644
USPC 257/88; 438/27

(57) ABSTRACT

A light engine with a heat sink having a curved recessed cavity that receives a flexed or cupped PCB bearing a plurality of LEDs. Once situated within the cavity and released, the PCB has a tendency to return to its flat state, but flanges or other suitable mechanisms at the ends of the cavity restrain the edges of the PCB and prevent the PCB from returning to its flat state. In this way, the PCB is securely retained within and biased against the cavity by its own forces. As the PCB heats, the PCB expands, further biasing the PCB against the cavity of the heat sink and increasing the thermal conductivity between the two components.

### FIELD OF THE INVENTION

Embodiments of the invention generally relate to light engines comprising flexed printed circuit boards and methods pertaining to the same.

### BACKGROUND OF THE INVENTION

Conventional light fixtures use light emitting diodes (“LEDs”) or other suitable light sources. Because LEDs and other light sources give off thermal energy, luminaire housings with heat sinks are sometimes incorporated into the light fixture to facilitate heat dissipation from the light sources. Such heat dissipation can result both from conduction of heat from the light sources via the heat sink material as well as convection of heat from the heat sink to the air circulating through and around the heat sink.

When LEDs are used as the light source, a printed circuit board (“PCB”) is typically populated with LEDs that are wired to the PCB. During assembly of the light fixture, the PCB (with LEDs mounted thereon) is typically fastened to the heat sink using either multiple screws or other suitable fasteners.

### SUMMARY OF THE INVENTION

The terms “invention,” “the invention,” “this invention” and “the present invention” used in this patent are intended to refer broadly to all of the subject matter of this patent and the patent claims below. Statements containing these terms should not be understood to limit the subject matter described herein or to limit the meaning or scope of the patent claims below. Embodiments of the invention covered by this patent are defined by the claims below, not this summary. This summary is a high-level overview of various aspects of the invention and introduces some of the concepts that are further described in the Detailed Description section below. This summary is not intended to identify key or essential features of the claimed subject matter, nor is it intended to be used in isolation to determine the scope of the claimed subject matter. The subject matter should be understood by reference to the entire specification of this patent, all drawings and each claim.

In certain embodiments there is provided a light engine with a heat sink having a curved recessed cavity that receives a flexed PCB bearing a plurality of LEDs. Once released, the elastic PCB has a tendency to attempt to return to its flat state. Flanges or other suitable mechanisms along the ends of the cavity, however, restrain the edges of the PCB and prevent the PCB from returning to its flat state. In this way, the PCB is securely retained within the cavity by its own forces. Moreover, the inability of the PCB to return to its natural state causes the PCB to bear against the curved surface of the cavity to increase its thermal contact with the underside of the cavity. Upon activation of the light source, the PCB heats up from the heat generated by the LEDs and expands, further biasing the PCB against the cavity of the heat sink and increasing the thermal conductivity between the two components.

### BRIEF DESCRIPTION OF THE DRAWINGS

A full and enabling disclosure including the best mode of practicing the appended claims and directed to one of ordinary skill in the art is set forth more particularly in the remainder of the specification. The specification makes reference to the following appended figures, in which use of like reference numerals in different features is intended to illustrate like or analogous components.

FIG. 1 is an exploded perspective view of portions of a light engine according to one embodiment, illustrating a printed circuit board going from a flat state to a flexed state for placement into a cavity of a heat sink.

FIG. 2 is an exploded view of a light engine according to another embodiment.

FIG. 3 is a perspective view of the light engine of FIG. 2 as assembled.

FIG. 4 is an assembled and partially cut-away view of the light engine of FIG. 2.

### DETAILED DESCRIPTION OF THE DRAWINGS

The subject matter of embodiments of the present invention is described here with specificity to meet statutory requirements, but this description is not necessarily intended to limit the scope of the claims. The claimed subject matter may be embodied in other ways, may include different elements or steps, and may be used in conjunction with other existing or future technologies. This description should not be interpreted as implying any particular order or arrangement among or between various steps or elements except when the order of individual steps or arrangement of elements is explicitly described.

FIG. 1 illustrates various components of a light engine 10 according to one embodiment of the invention. Light engine 10 comprises a heat sink 12. The side of heat sink 12 that faces the area to be lit includes a recessed cavity 14 that is sized and shaped to receive a printed circuit board (PCB) 18 having a plurality of LEDs 22 mounted thereon. In some embodiments, PCB has chip-on-board technology. A plurality of fins 17 or other extended surfaces may, but do not have to, project from the other side of heat sink 12 and allow for convective cooling of heat dissipated through heat sink 12.

Cavity 14 may have a generally rectilinear, single-axis concave shape such that cavity 14 has a slightly curved upper surface 15. As one non-limiting example, cavity 14 may be recessed such that the general mid-point of cavity 14 is recessed approximately 0.200 inches as compared with the ends of the cavity. In some embodiments, cavity 14 includes one or more flanges 16 that extend at least partially along two opposing generally straight ends 13 of cavity 14. Each flange 16 serves as an edge-constraint along each generally straight end 13. In other embodiments, instead of flanges 16, other suitable mechanisms are used to restrain the edges 20 of PCB 18 within cavity 14 and prevent PCB from returning to its natural flat state as described in detail below.

In some embodiments, PCB 18 is a substantially rigid board that elastically deforms. In other words, when flexed below its yield point, PCB 18 attempts to recover and return to its naturally flat state (as opposed to plastic deformation where the board would be permanently deformed with no ability to return to its original shape). In some embodiments, PCB 18 is a metal core board or made of another suitable material. PCB 18 may be covered by a flexible dielectric material that enables the board to flex slightly without cracking components on the board or causing the components to lose connectivity with the board. In some cases, the dielectric layer is both stretchable and flexible/bendable so that it can elastically deform so as to prevent the dielectric layer from both cracking and delaminating during the deformation process. One non-limiting example of such a resilient dielectric layer is sold by Dupont™ under the tradename CooLam™.

As shown in FIG. 1, PCB 18 may be flexed or cupped slightly toward the cavity 14 so that it generally mirrors the curvature of recessed cavity 14. The curvature of the recessed cavity 14 is such that, to generally mirror the curvature of recessed cavity 14, PCB 18 only needs to be flexed or cupped slightly below its yield point so that it is in the elastic deformation range. PCB 18 can then be situated in its slightly cupped state within cavity 14 so that the LEDs 22 face downwardly toward the area to be lit. PCB 18 may then be released. Because PCB 18 has been flexed toward cavity 14 and because PCB 18 has elastically deformed, its natural tendency is to return to its original flat state. Flanges 16 of cavity 14, however, constrain edges 20 of PCB 18 and prevent PCB 18 from returning to its flat state. Thus, the only available movement for PCB 18 is to arch further towards the curved upper surface 15 of cavity 14 such that PCB 18 is in thermal contact with the curved upper surface 15 of cavity 14. In this way, the natural tendency of PCB 18 to return to its flat state dynamically biases PCB 18 against the curved upper surface 15 of cavity 14 (similar to how a playing card can be “palmed”). As a result, PCB 18 is retained tightly and evenly against the curved upper surface 15 by its own forces without the need for mechanical fasteners or other clamping devices to ensure such thermal contact.

Because PCB 18 is held tightly against the curved upper surface 15 of cavity 14 by its own internal forces, thermal conductivity between PCB 18 and heat sink 12 is increased, which leads to greater heat dissipation. Moreover, as PCB 18 heats from the heat generated by the LEDs or other light source, PCB 18 expands. However, PCB 18 is constrained by the edges of cavity 14, and thus, upon such expansion, is only able to elastically deform even further towards curved upper surface 15. Thus, PCB 18 is retained even more tightly within, and biased more securely against, cavity 14 when the LEDs are in use and such contact is the most critical.

In some embodiments, as shown in FIG. 2, a thermal pad 24 may optionally be positioned between PCB 18 and cavity 14. If used, thermal pad 24 provides resilience and may facilitate thermal connectivity between PCB 18 and cavity 14. Thermal pad 24 may be retained within cavity 14 in a similar way as PCB 18 as described above.

Moreover, a lens sheet 26 may be overlaid on PCB 18. If used, lens sheet 26 may be injection-molded plastic or other suitable material and may have a plurality of lenses 19 that align with LEDs 22 of PCB 18. Lens sheet 26 may be transparent or semi-transparent. If used, lens sheet 26 may be molded into the same shape and general curvature as the flexed PCB 18. Lens sheet 26 may then be overlaid onto PCB 18 and positioned within cavity 14. Like PCB 18, the edges of lens sheet 26 will be tightly edge-constrained by flanges 16 of cavity 14. Moreover, because lens sheet 26 is plastic or other suitable material that expands as it heats, a tight fit between PCB 18 and lens sheet 26 is achieved as discussed above with respect to PCB 18. Optionally, a suitable perimeter sealing device or method may be used to further constrain lens sheet 26 within cavity 14. One non-limiting example is a resilient O-ring that may be inserted into a groove around the outside of the lens sheet (not pictured) and used to further secure the lens sheet within cavity 14. If desired, lens sheet 26 may also be mechanically fastened to heat sink 12 to aid with retention. Because lens sheet 26 is tightly restrained within cavity 14, it is less likely that lenses 19 will shift relative to LEDs 22.

FIG. 2 also illustrates a lens cover 28 that may be overlaid against lens sheet 26 in some embodiments. If used, lens cover 28 clamps the perimeter of lens sheet 26 and compresses lens sheet 26, sealing the assembly against the heat sink 12. Lens cover 28 may include a plurality of openings 30 that align with lenses 19 such that, when assembled, lenses 19 protrude through openings 30 and permit light to exit the assembly. FIG. 3 illustrates the entire sandwiched assembly 10, while FIG. 4 shows a partially cut-away view of the sandwiched assembly 10.

Embodiments of the light engine 10 disclosed herein may be incorporated into any light fixture or luminaire.

Also disclosed is a method of mounting a PCB such as PCB 18 into a heat sink such as heat sink 12 as described above and a method of using the light engine 10. In one embodiment, a PCB 18 is mounted as described above and the LEDs 22 are powered on. As the LEDs 22 on the PCB 18 heat up, the PCB 18 heats up and expands and continues to attempt to return to its flat state due to its elastic deformation. Because the PCB 18 is constrained around its edges 20 by flanges 16, the PCB's only permitted movement is to arch more against cavity 14. As described above, as it arches more, the PCB 18 bears more tightly against the surface 15 of cavity 14 (or against thermal pad 24 if one is used), thus increasing thermal efficiency, both in contact pressure and path length.

As the LEDs 22 heat up, the lens sheet 26, if used, also expands due to the material properties of the lens sheet 26. Like the PCB 18, the lens sheet 26 is constrained around its perimeter and is thus only permitted to press itself more tightly against the PCB 18. To counteract any stresses built in the lens sheet, the lens sheet 26 optionally may be designed with movement-absorbing features such as corrugations or other suitable ways of lowering stresses below the elastic limit of the material of the lens sheet 26.

Because separate mechanical fasteners are not required to secure the PCB 18 to the heat sink 12, the raw material, tooling and assembly costs of the light engine 10 are reduced. Moreover, connecting a PCB to a heat sink using mechanical fasteners makes the process much more time intensive, so the above assembly and methods decrease the time and expense associated with assembling the PCB 18 within the heat sink 12. Similarly, because the lens sheet 26 is restrained within cavity 14 of heat sink 12 without the need for mechanical fasteners, material and assembly costs are reduced. Moreover, the tight connection between the lens sheet 26 and the heat sink cavity 14 helps ensure that the lenses 19 do not move relative to LEDs 22. In addition, the tight seal between the lens sheet 26 and the PCB 18 helps protect the PCB 18 and the LEDs 22 against the environment in a reliable and consistent fashion.

The foregoing is provided for purposes of illustrating, explaining, and describing embodiments of the present invention. Further modifications and adaptations to these embodiments will be apparent to those skilled in the art and may be made without departing from the scope or spirit of the invention. Different arrangements of the components depicted in the drawings or described above, as well as components and steps not shown or described are possible. Similarly, some features and subcombinations are useful and may be employed without reference to other features and subcombinations. Embodiments of the invention have been described for illustrative and not restrictive purposes, and alternative embodiments will become apparent to readers of this patent. Accordingly, the present invention is not limited to the embodiments described above or depicted in the drawings, and various embodiments and modifications can be made without departing from the scope of the claims below.

I claim:

1. A light engine comprising:
(a) a heat sink comprising a cavity having an upper surface having a curvature, wherein opposing ends of the cavity comprise at least one flange;
(b) a printed circuit board comprising a first surface, a second surface opposite the first surface, a plurality of light emitting diodes mounted on the second surface, wherein the printed circuit board is elastically deformed and positioned within the cavity such that the printed circuit board comprises a curvature substantially the same as the curvature of the upper surface of the heat sink cavity, wherein the at least one flange on the opposing ends of the heat sink engage edges of the printed circuit board to prevent the printed circuit board from returning to a generally flat configuration and wherein the first surface of the printed circuit board is biased against the upper surface of the cavity so the printed circuit board is secured within the cavity and is in thermal contact with the upper surface of the cavity.

2. The light engine of claim 1, wherein the cavity has a generally rectilinear shape.

3. The light engine of claim 1, wherein the printed circuit board is retained within the cavity entirely by interaction between the flanges and the printed circuit board as the printed circuit board attempts to return to its generally flat configuration.

4. The light engine of claim 1, wherein upon activation of the light emitting diodes, heat generated by the light emitting diodes causes the printed circuit board to expand within the cavity to further bias the first surface of the printed circuit board against the upper surface of the cavity to increase the thermal contact between the printed circuit board and the upper surface of the cavity.

5. The light engine of claim 1, further comprising a thermal pad positioned between the cavity and the printed circuit board.

6. The light engine of claim 1, further comprising a lens sheet positioned on the printed circuit board.

7. The light engine of claim 6, wherein the lens sheet comprises a curvature substantially the same as the curvature of the printed circuit board.

8. The light engine of claim 6, wherein the at least one flange on opposing ends of the cavity restrains the lens sheet within the cavity.

9. The light engine of claim 6, wherein the lens sheet further comprises a plurality of lenses that generally align with the light emitting diodes of the printed circuit board when the lens sheet is positioned on the printed circuit board.

10. The light engine of claim 9, further comprising a lens cover positioned on the lens sheet, wherein the lens cover comprises a plurality of openings through which the plurality of lenses protrude when the lens cover is positioned on the lens sheet.

11. A method of securing a printed circuit board capable of elastic deformation and having a plurality of light emitting diodes within a curved cavity of a heat sink comprising:
bending the printed circuit board from a flat configuration into a curved configuration so that the printed circuit board is elastically deformed and generally mirrors a curvature of the curved cavity;
positioning the printed circuit board in the curved configuration within the curved cavity; and
releasing the printed circuit board within the curved cavity such that the printed circuit board attempts to return to the flat configuration but is prevented from returning to the flat configuration by flanges along the ends of the curved cavity that constrain edges of the printed circuit board.

12. The method of claim 11, wherein the prevention of the printed circuit board from returning to the flat configuration biases the printed circuit board against a surface of the curved cavity.

13. The method of claim 12, further comprising activating the light emitting diodes such that the printed circuit board expands.

14. The method of claim 13, wherein the expansion of the printed circuit board further restrains the printed circuit board within the cavity and biases the printed circuit board against the surface of the cavity.

15. The method of claim 11, further comprising positioning a thermal pad between the printed circuit board and the curved cavity.

16. The method of claim 11, further comprising positioning a lens sheet comprising a plurality of lenses on the printed circuit board such that the plurality of lenses align with the light emitting diodes.

17. The method of claim 16, further comprising positioning a lens cover comprising a plurality of openings on the lens sheet such that the plurality of lenses protrude through the plurality of openings.

18. The method of claim 16, wherein the flanges of the cavity restrain the lens sheet and prevent the plurality of lenses from shifting relative to the light emitting diodes.
